(19) United States
(12) Patent Application Publication
(10) Pub. No.: US 2008/0048191 A1
(43) Pub. Date: Feb. 28, 2008

(54) Organic light emitting display device and method of fabricating the same

(76) Inventor: Hyun Chul Son, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 11/730,796

(22) Filed: Apr. 4, 2007

(30) Foreign Application Priority Data
Aug. 23, 2006 (KR) 10-2006-0079931

(51) Int. Cl. H01L 31/00; H01J 1/62

(52) U.S. Cl. 257/72; 313/506; 257/E31.001

(57) ABSTRACT

A display device includes a substrate having a transistor disposed thereon and including a source/drain electrode connected to the transistor, an intermediate layer disposed on the transistor, the source/drain electrode penetrating the intermediate layer, a light emitting structure disposed on the intermediate layer, the light emitting structure connected to an extension portion of the source/drain electrode by a first electrode, the extension portion extending across an upper surface of the intermediate layer, a first opening in the upper surface of the intermediate layer where the source/drain electrode penetrates the intermediate layer, and a contact area where the first electrode contacts the source/drain electrode, wherein the contact area has an area greater than that of the first opening, and the contact area does not overlap the first opening.

### BACKGROUND OF THE INVENTION

1. Field of the Invention

The present invention relates to an organic light emitting display device and fabricating method of the same. More particularly, the present invention relates to an organic light emitting display device having improved contact resistance and fabricating method of the same.

2. Description of the Related Art

Recently, various types of flat display devices have been developed in which disadvantages of cathode ray tube-based display devices, such as weight and volume, have been addressed. Such flat display devices include, e.g., liquid crystal display devices, field emission display devices, plasma display devices, organic light emitting display devices, etc. Of these, the organic light emitting display device (OLED display device) generates visible light, e.g. to display a picture, by the recombination of electrons and holes in an organic layer. The OLED display device may offer various advantages such as rapid response times, low power consumption, wide viewing angle, etc.

Active matrix display devices may include one or more transistors for each light emitting pixel. As the size of the display is reduced, e.g., to implement the display device in portable electronic equipment, or as the resolution of the display device is increased, the cell size must also be reduced. This may require a reduction in the area occupied by the transistor(s) and the interconnections therefore. Accordingly, further developments are needed to enable the manufacturing of small cell size display devices.

### SUMMARY OF THE INVENTION

The present invention is therefore directed to an organic light emitting display device and a method of fabricating the same, which substantially overcome one or more of the problems due to the limitations and disadvantages of the related art.

It is therefore a feature of an embodiment of the present invention to provide an organic light emitting display device and a method of fabricating the same that enable the manufacturing of small cell size display devices without undue increases in contact defects and contact resistance.

It is therefore another feature of an embodiment of the present invention to provide an organic light emitting display device and a method of fabricating the same that reduce the need to form high aspect ratio features during fabrication.

At least one of the above and other features and advantages of the present invention may be realized by providing a display device including a substrate having a transistor disposed thereon and including a source/drain electrode connected to the transistor, an intermediate layer disposed on the transistor, the source/drain electrode penetrating the intermediate layer, a light emitting structure disposed on the intermediate layer, the light emitting structure connected to an extension portion of the source/drain electrode by a first electrode, the extension portion extending across an upper surface of the intermediate layer, a first opening in the upper surface of the intermediate layer where the source/drain electrode penetrates the intermediate layer, and a contact area where the first electrode contacts the source/drain electrode, wherein the contact area has an area greater than that of the first opening, and the contact area does not overlap the first opening.

The display device may further include an insulation layer and a second intermediate layer, wherein the source/drain electrode penetrates the insulation layer, the insulating layer being disposed between the substrate and the intermediate layer and between a gate electrode of the transistor and a channel region of the transistor, and the first electrode penetrates the second intermediate layer, the intermediate layer being disposed between the second intermediate layer and the insulation layer. The display device may further include a planarization layer disposed on the second intermediate layer and having a substantially flat top surface.

The source/drain electrode may be disposed in a contact hole that extends through the intermediate layer, the first electrode may be disposed in a via hole, a lower opening of the via hole exposing the contact area, and the via hole may be larger than the contact hole in a layout of the display device. The display device may further include a second intermediate layer on the intermediate layer, wherein the via hole extends through the second intermediate layer, the lower opening may be in a lower surface of the second intermediate layer, and an area of the lower opening of the via hole may be equal to the contact area.

The source/drain electrode may be disposed in a contact hole that extends through the intermediate layer, the first electrode may be disposed in a via hole, a lower opening of the via hole exposing the contact area, and the via hole may not overlap the contact hole in a layout of the display device. The via hole and the contact hole may be spaced apart by about 1 μm to 2 μm.

The first electrode may include a first electrode layer and a second electrode layer. The first electrode layer may be a reflective layer and the second electrode layer may be a transparent conductive layer. The display device may further include a second intermediate layer on the intermediate layer, the first electrode being disposed in a via hole that penetrates the second intermediate layer and exposes the extension portion of the source/drain electrode, wherein the first electrode layer may be disposed between the second electrode layer and the second intermediate layer, and the second electrode layer may directly contact the source/drain electrode at a lower opening of the via hole.

The source/drain electrode may be disposed in a contact hole, the first electrode may be disposed in a via hole, a lower opening of the via hole exposing the contact area, the via hole may have a short side and a long side, the short side of the via hole may be wider than a width of the contact hole, the short side of the via hole may extend away from the contact hole in a first direction, and the long side of the via hole may extend in a second direction substantially perpendicular to the second direction. A peripheral portion of the source/drain electrode may completely surround the contact hole and the via hole in a layout of the display device. The via hole may overlap a gate electrode of the transistor in the layout.

The first electrode may be disposed in a via hole, the display device may further include a second via hole, the first electrode also being disposed in the second via hole, and the first electrode may also contact the source/drain electrode in a second contact area that is exposed by a lower opening of the second via hole. The second via hole may overlap a gate electrode of the transistor. The transistor may include a gate electrode and two source/drain regions, and the gate electrode may have a width that is narrower than a width of either of the source/drain regions.

At least one of the above and other features and advantages of the present invention may be realized by providing a method of fabricating a display device, including forming a transistor on a substrate, forming an intermediate layer on the transistor, forming a source/drain electrode in a contact hole through the intermediate layer, the source/drain electrode being connected to the transistor and having an extension portion extending across an upper surface of the intermediate layer, forming a via hole that exposes the extension portion, and forming a light emitting structure on the intermediate layer, the light emitting structure being connected to the extension portion by a first electrode that is disposed in the via hole, wherein a contact area where the first electrode contacts the source/electrode has an area greater than an area of an opening of the contact hole at an upper surface of the intermediate layer, and the contact area does not overlap the opening.

The first electrode may include a first electrode layer and a second electrode layer, and forming the first electrode may include forming the first electrode layer on the substrate and in the via hole, the first electrode layer being on the contact area, removing the first electrode layer from the contact area, and forming the second electrode layer on the first electrode layer and on the contact area such that the second electrode layer directly contacts the source/drain electrode in the contact area. The first electrode layer may be a reflective layer and the second electrode layer may be a transparent conductive layer. Removing the first electrode layer from the contact area may include forming a photoresist layer on the first electrode layer, the photoresist layer filling the via hole, removing the photoresist layer from the via hole to expose the first electrode layer, and removing the first electrode layer from the via hole where it is exposed by the photoresist layer. The photoresist layer may be a positive photoresist. The via hole may overlap a gate electrode of the transistor in the layout. The method may further include forming a passivation layer on the intermediate layer and on the source/drain electrode, and forming a planarization layer on the passivation layer.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a cross-sectional view of an organic light emitting display device according to a first embodiment of the present invention;

FIG. 2 illustrates an exemplary partial layout diagram of an organic light emitting display device according to the first embodiment of the present invention;

FIG. 3 illustrates a second exemplary partial layout diagram of an organic light emitting display device according to the first embodiment of the present invention;

FIG. 4 illustrates a third exemplary partial layout diagram of an organic light emitting display device according to the first embodiment of the present invention;

FIG. 5 illustrates a fourth exemplary partial layout diagram of an organic light emitting display device according to the first embodiment of the present invention;

FIG. 6 illustrates a cross-sectional view of a conventional organic light emitting display device; and

FIG. 7 illustrates a partial layout diagram of FIG. 6.

### DETAILED DESCRIPTION OF THE INVENTION

Korean Patent Application No. 10-2006-0079931, filed on Aug. 23, 2006, in the Korean Intellectual Property Office, and entitled: “Organic Light Emitting Display Device and Fabricating Method of the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

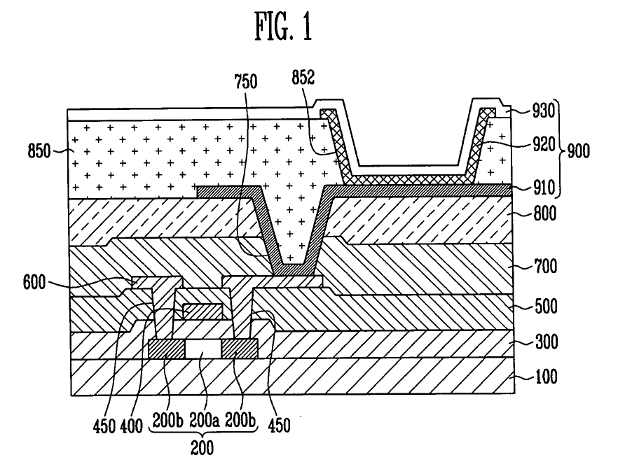

FIG. 1 illustrates a cross-sectional view of an OLED display device according to a first embodiment of the present invention. Referring to FIG. 1, the OLED display device according to the first embodiment of the present invention may include an OLED structure coupled to a transistor. In particular, a substrate 100 may have a semiconductor layer 200, a gate insulating layer 300, a gate electrode 400, an intermediate layer 500, e.g., an inter-layer insulating layer, source/drain electrodes 600, a second intermediate layer 700, e.g., a passivation layer, a planarization layer 800, and an OLED structure 900 thereon. The OLED structure 900 may be driven by a first electrode 910 and a second electrode 930. One or more organic material-containing layers 920 may be interposed between the first electrode 910 and the second electrode 930.

In greater detail, the semiconductor layer 200 may be formed on the substrate 100 and may include a channel region 200a and source/drain regions 200b. The semiconductor layer 200 may be formed by, e.g., vapor depositing, patterning and crystallizing amorphous silicon. The semiconductor layer 200 may be doped in a predetermined area, e.g., with p-type or n-type impurities using ion implantation, to form the source/drain regions 200b. The gate insulating layer 300 may be disposed on the semiconductor layer 200 and the substrate 100. The gate insulating layer 300 may electrically insulate the gate electrode 400 from the semiconductor layer 200.

The gate electrode 400 may be disposed on the gate insulating layer 300, e.g., by vapor depositing and patterning a conductive material, e.g., a metal. In the transistor, the gate electrode 400 may have a width corresponding to the channel region 200a of the semiconductor layer 200. The inter-layer insulating layer 500 may be disposed on the gate electrode 400 and on the gate insulating layer 300.

The source/drain electrodes 600 may each be disposed on the inter-layer insulating layer 500 and in respective contact holes 450 that penetrate the inter-layer insulating layer 500 and the gate insulating layer 300. The source/drain electrodes 600 may be electrically connected to the respective source/drain regions 200b. The contact holes 450 may be formed through the inter-layer insulating layer 500 and the gate insulating layer 300 using, e.g., an etching process.

The passivation layer 700 may be disposed on the inter-layer insulating layer 500 and on the source/drain electrodes 600, and the planarization layer 800 may be disposed on the passivation layer 700. A surface of the planarization layer 800 that faces the OLED structure 900, i.e., an upper surface, may be planarized. A pixel defining layer 850 may be disposed on the planarization layer 800. The pixel defining layer may have an opening 852 defined therein that exposes a portion of the first electrode 910.

The OLED structure 900 may be disposed on the planarization layer 800, and may be electrically connected to a source/drain electrode 600 through a via hole 750 that penetrates the passivation layer 700 and the planarization layer 800 and exposes a portion of the source/drain electrode 600. The via hole 750 may be formed by, e.g., etching the planarization layer 800 and the passivation layer 700. The via hole 750 may not overlap the contact hole 450, a feature that will be described in additional detail below.

The first electrode 910 may be disposed in the via hole 750 and on the planarization layer 800. The organic material-containing layer(s) 920 may be on the first electrode 910, between and electrically connected to the first electrode 910 and the second electrode 930. The first electrode 910 may serve as an anode electrode.

In an implementation, the first electrode 910 may include first and second electrode layers such as a reflective layer, e.g., aluminum or an aluminum-containing layer such as AlNd, and a transparent conductive layer, e.g., ITO. The reflective layer may be formed on the planarization layer 800 and in the via hole 750, after which the transparent layer may be formed on the reflective layer. Where the reflective layer includes aluminum, the contact resistance between the first electrode 910 and the underlying source/drain electrode 600 may increase if the aluminum is oxidized to form a film, e.g., an Al₂O₃ film. Accordingly, after depositing the reflective layer, a photoresist layer may be formed on the substrate so that the reflective layer may be patterned, i.e., removed, from a contact area of the via hole 750 using a photo-etching process so as to expose the underlying source/drain electrode 600. After removing the portion of the reflective layer that overlies the source/drain electrode 600, the transparent layer may be deposited in the via hole 750 to directly contact the source/drain electrode 600, thereby avoiding the deleterious effects of an oxidized aluminum film in the contact area.

The passivation layer 700 and/or the planarization layer 800 may be formed using, e.g., a PVX (phosphorous-doped vapor deposited silicon oxide) system. In such a case, the step thickness, i.e., the thickness of the layers 700 and/or 800, may be increased. As a result, it may be difficult to completely remove the photoresist layer from the via hole 750. For example, a positive photoresist layer may not expose completely when patterning the photoresist layer in the via hole 750 if the via hole 750 is too deep or has too high an aspect ratio. Thus, some of the photoresist layer may remain in the via hole 750 after the patterning procedure. This remaining photoresist may cause a pattern error in the first electrode 910 during formation thereof in a subsequent procedure.

Accordingly, in the first embodiment of the present invention, the via hole 750 may not overlap the contact hole 450 and the size of the via hole 750 may be increased relative to the size of the contact hole 450. Accordingly, the aspect ratio of the via hole 750 may be reduced, which may reduce or eliminate difficulties associated with patterning and removing the photoresist layer from the via hole 750. Moreover, the increased size of the via hole 750 may allow for a greater contact area between the first electrode 910 in the via hole 750 and the underlying portion of the source/drain electrode 600, which may be an extension portion of the source/drain electrode 600 that extends over the inter-layer insulating layer 500. Therefore, according to this embodiment of the present invention, the resolution of the OLED display device may be increased, with a corresponding reduction in individual cell size, while reducing or eliminating the need for undue increases in hole aspect ratios and/or decreases in contact areas. That is, by laterally separating the via hole 750 and the contact hole 450, the size of the via hole 750 may be increased and the electrical characteristics of the OLED display device may be enhanced, e.g., by lowering the contact resistance.

In contrast to the embodiment described above, in a conventional OLED display device, the contact hole and the via hole may be directly superimposed in the vertical direction, which necessitates forming a hole structure with an excessively high aspect ratio and which may lead to difficulties in processing a photoresist layer formed therein. Moreover, a contact region between an electrode in the contact hole and an electrode in the via hole may be restricted, leading to undesirably high contact resistance therebetween.

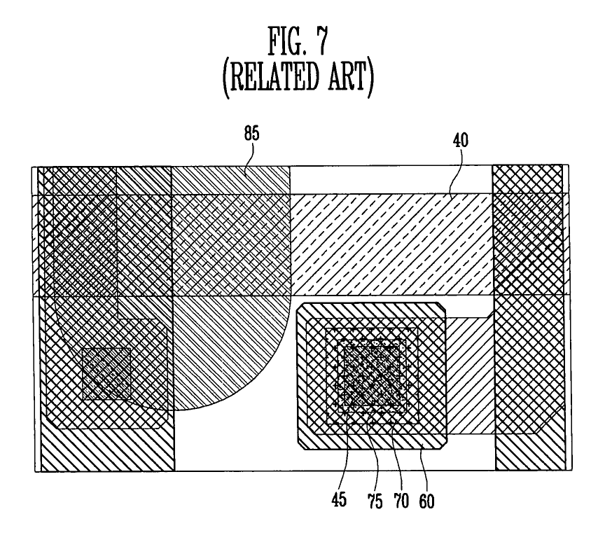

In particular, referring to FIGS. 6 and 7, which illustrate cross-sectional and layout views of a conventional OLED display device, respectively, a via hole 75 is directly superimposed on a contact hole 45. The conventional OLED display device may include a substrate 10, a semiconductor layer 20, a gate insulating layer 30, a gate electrode 40, a inter-insulating layer 50, source/drain electrodes 60, a passivation layer 70, a planarization layer 80, a pixel-defining layer 85 and an OLED structure 90. The semiconductor layer 20 may include a channel region 20a and source/drain regions 20b. The OLED structure 90 may include a first electrode 91, an organic material-containing layer 92 and a second electrode 93.

As illustrated in FIGS. 6 and 7, the contact hole 45 may penetrate the gate insulating layer 30 and the inter-insulating layer 50, and the via hole 75 may penetrate the passivation layer 70 and the planarization layer 80. The via hole 75 may be formed by etching the planarization layer 80 and the passivation layer 70. However, since the via hole 75 is directly superimposed on the contact hole 45, the aspect ratio of the via hole 75 may be high, i.e., the hole may be very narrow in relation to its depth. Therefore, a photoresist film that is formed in the via hole 75 may be difficult or impossible to expose properly, and photoresist film may remain in the via hole 75 after the patterning process is completed. This patterning fault may lead to defects in the subsequently formed first electrode 91.

Moreover, in the conventional device, it is apparent that the size of the via hole 75 where it contacts the source/drain electrode 60 is small, corresponding to the size of the contact hole 45. Accordingly, there is a greater likelihood of a contact fault occurring at the interface of the first electrode 91, which is disposed in the via hole 75, and the underlying source/drain electrode 60. Further, the small size of the first electrode 91 in the via hole 75 may lead to a greater contact resistance where the first electrode 91 contacts the source/drain electrode 60. Moreover, it will be appreciated that these limitations of the conventional OLED display device would be exacerbated by increasing the resolution of the device, i.e., by reducing the cell size.

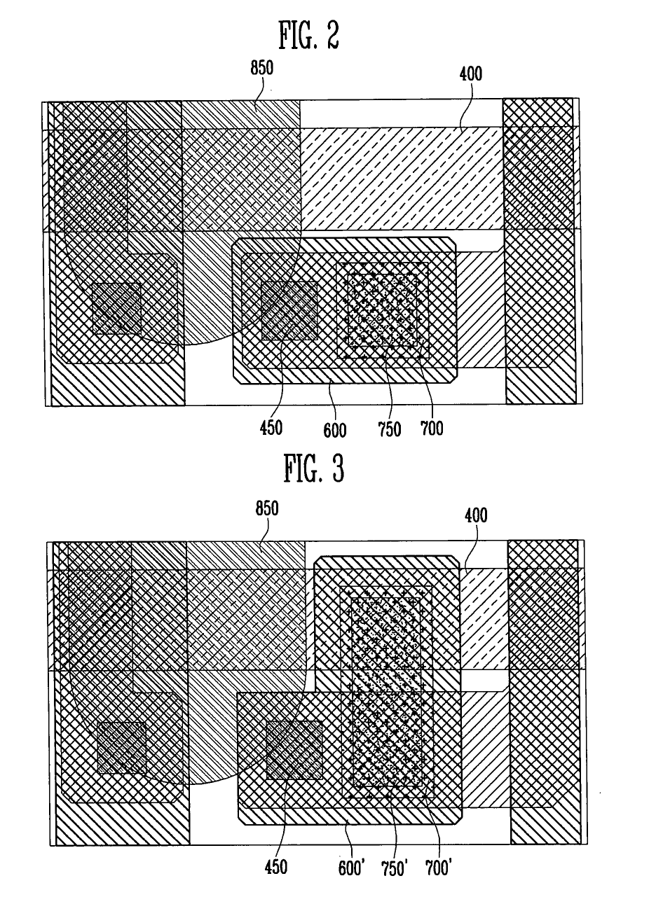

FIGS. 2-5 illustrate exemplary partial layout diagrams of an organic light emitting display device according to the first embodiment of the present invention. Referring to FIGS. 2-5, the contact hole 450 and the via hole 750 may be spaced apart. In the particular examples illustrated in FIGS. 2-5, the contact hole 450 and the via hole 750 may have peripheries that are separated by a predetermined distance.

As illustrated in FIGS. 2-5, the contact hole 450 and the via hole 750 may not overlap. For example, referring to FIG. 2, the contact hole and the via hole 750 may be separated in a lateral direction and may be centered on a common line, i.e., they may have a common horizontal axis as illustrated in FIG. 2. The source/drain electrode 600 may extend between the via hole 750 and the contact hole 450, and a peripheral portion of the source/drain electrode 600 may surround the via hole 750 and the contact hole 450. The area of the via hole 750 at a bottom surface of the passivation layer 700 on the source/drain electrode 600 may be larger than an area of the contact hole 450 at the bottom surface of the passivation layer 700.

Referring again to FIG. 1, the contact hole 450 and the via hole 750 may extend through the gate insulating layer 300, the inter-layer insulating layer 500, the passivation layer 700 and planarization layer 800, without creating a hole that is too deep and narrow. In accordance with the present invention, the contact hole 450 may have a height, i.e., a dimension determined normal to the substrate, that corresponds to the sum of the thicknesses of the gate insulating layer 300 and the inter-layer insulating layer 500 on the source/drain region 200b. The via hole 750 may have a height that corresponds to the sum of the thicknesses of the passivation layer 700 and planarization layer 800 on the source/drain electrode 600. In an implementation, the via hole 750 and the contact hole 450 may be separated by a predetermined distance, e.g., about 1 μm to about 2 μm. Of course, it will be appreciated that other suitable arrangements of the contact hole 450 and the via hole 750 may be provided.

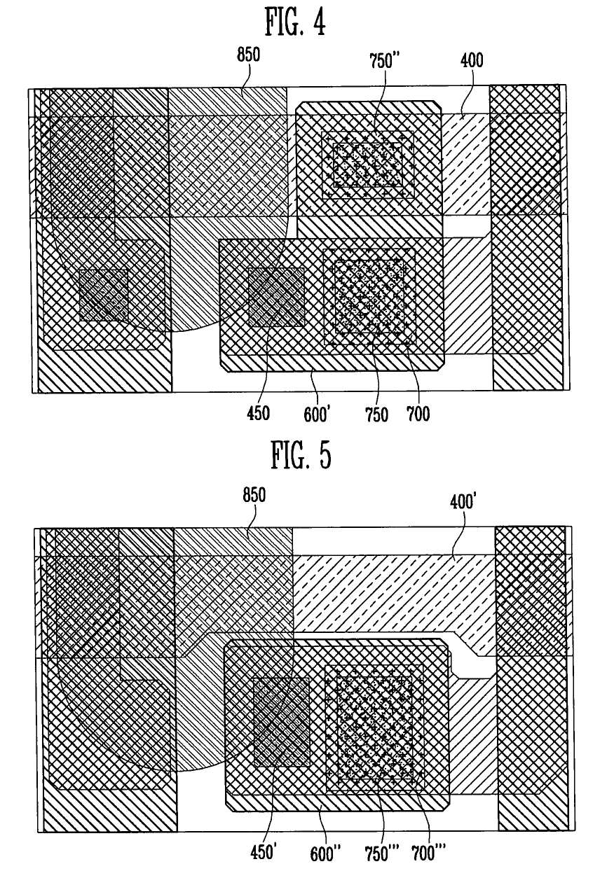

Referring to FIG. 3, a via hole 750′ may be formed that is enlarged relative to the via hole 750 in the example illustrated in FIG. 2. In an implementation, the via hole 750′ may have a generally rectangular aspect in plan view, e.g., having a width to length ratio of about 1:2. Also, where the via hole 750′ passes through the passivation layer 700′, the via hole 750′ may have a longer dimension, i.e., it may have a length of about two times (2×) that of the via hole 750 illustrated in FIG. 2. Similarly, an enlarged source/drain region 600′ may be provided that surrounds the via hole 750′ as well as the contact hole 450. Thus, the size of the via hole 750′ corresponding to the contact area between the first electrode 910 formed in the via hole 750′ and the underlying source/drain electrode 600′, and thus the corresponding contact area as well, may be increased while maintaining the separation between the via hole 750′ and the contact hole 450. By enlarging the size of the via hole 750′, a greater electric current may be passed through the contact area. This may enhance electrical characteristics such as the transfer of a data signal to the first electrode 910, which may serve as the anode electrode.

FIG. 4 illustrates a third exemplary partial layout diagram of an organic light emitting display device according to the first embodiment of the present invention. Referring to FIG. 4, the effective size of the contact area may be increased by providing multiple via holes 750 and 750″ on the source/drain electrode 600′. The first electrode 910 may be formed in both of the via holes 750 and 750″ to contact the source/drain electrode 600 twice, i.e., it may be common to both via holes 705 and 750″. As illustrated in FIG. 4, all or a portion of the via hole 750″ may overlap with the gate electrode 400.

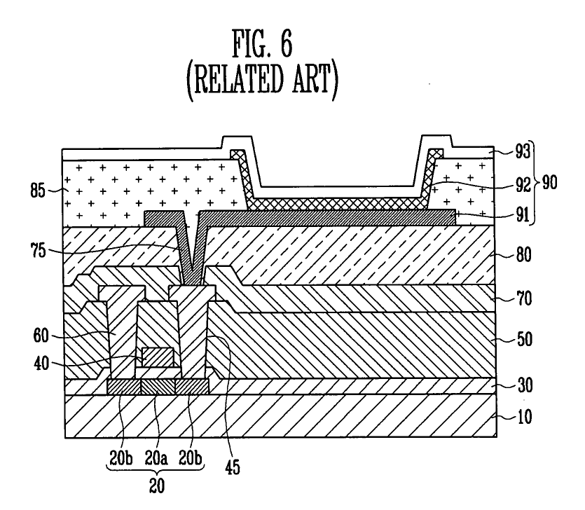

FIG. 5 illustrates a fourth exemplary partial layout diagram of an organic light emitting display device according to the first embodiment of the present invention. Referring to FIG. 5, in this example, both a contact hole 450′ and a via hole 750′″ may have a generally rectangular aspect in plan view, with a length, i.e., a vertical dimension in FIG. 5, being extended relative to the width. A source/drain electrode 600″ may be similarly extended so as to surround the contact hole 450′ and the via hole 750′″. In an implementation, a patterned gate electrode 400′ may be provided that does not overlap the source/drain electrode 600″, which may enable a reduction in parasitic capacitance therebetween.

Also, since the overlap of the gate electrode 400′ with the contact hole 450′ and the via hole 750′″ may be removed, the region of the gate electrode 400′ may be decreased relative to the source/drain regions 200b. That is, the gate electrode 400′ may be formed with a narrower width than the source/drain electrodes 200b.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A display device, comprising;
a substrate having a transistor disposed thereon and including a source/drain electrode connected to the transistor;
an intermediate layer disposed on the transistor, the source/drain electrode penetrating the intermediate layer;
a light emitting structure disposed on the intermediate layer, the light emitting structure connected to an extension portion of the source/drain electrode by a first electrode, the extension portion extending across an upper surface of the intermediate layer;
a first opening in the upper surface of the intermediate layer where the source/drain electrode penetrates the intermediate layer; and
a contact area where the first electrode contacts the source/drain electrode,
wherein the contact area has an area greater than that of the first opening, and
the contact area does not overlap the first opening.

2. The display device as claimed in claim 1, further comprising an insulation layer and a second intermediate layer, wherein:
the source/drain electrode penetrates the insulation layer, the insulating layer being disposed between the substrate and the intermediate layer and between a gate electrode of the transistor and a channel region of the transistor, and
the first electrode penetrates the second intermediate layer, the intermediate layer being disposed between the second intermediate layer and the insulation layer.

3. The display device as claimed in claim 2, further comprising a planarization layer disposed on the second intermediate layer and having a substantially flat top surface.

4. The display device as claimed in claim 1, wherein the source/drain electrode is disposed in a contact hole that extends through the intermediate layer,
the first electrode is disposed in a via hole, a lower opening of the via hole exposing the contact area, and
the via hole is larger than the contact hole in a layout of the display device.

5. The display device as claimed in claim 4, further comprising a second intermediate layer on the intermediate layer, wherein the via hole extends through the second intermediate layer,
the lower opening is in a lower surface of the second intermediate layer, and
an area of the lower opening of the via hole is equal to the contact area.

6. The display device as claimed in claim 1, wherein the source/drain electrode is disposed in a contact hole that extends through the intermediate layer,
the first electrode is disposed in a via hole, a lower opening of the via hole exposing the contact area, and
the via hole does not overlap the contact hole in a layout of the display device.

7. The display device as claimed in claim 6, wherein the via hole and the contact hole are spaced apart by about 1 μm to 2 μm.

8. The display device as claimed in claim 1, wherein the first electrode includes a first electrode layer and a second electrode layer.

9. The display device as claimed in claim 8, wherein the first electrode layer is a reflective layer and the second electrode layer is a transparent conductive layer.

10. The display device as claimed in claim 8, further comprising a second intermediate layer on the intermediate layer, the first electrode being disposed in a via hole that penetrates the second intermediate layer and exposes the extension portion of the source/drain electrode,
wherein the first electrode layer is disposed between the second electrode layer and the second intermediate layer, and
the second electrode layer directly contacts the source/drain electrode at a lower opening of the via hole.

11. The display device as claimed in claim 1, wherein:
the source/drain electrode is disposed in a contact hole,
the first electrode is disposed in a via hole, a lower opening of the via hole exposing the contact area,
the via hole has a short side and a long side,
the short side of the via hole is wider than a width of the contact hole,
the short side of the via hole extends away from the contact hole in a first direction, and
the long side of the via hole extends in a second direction substantially perpendicular to the second direction.

12. The display device as claimed in claim 11, wherein a peripheral portion of the source/drain electrode completely surrounds the contact hole and the via hole in a layout of the display device.

13. The display device as claimed in claim 12, wherein the via hole overlaps a gate electrode of the transistor in the layout.

14. The display device as claimed in claim 1, wherein the first electrode is disposed in a via hole,
the display device further comprises a second via hole, the first electrode also being disposed in the second via hole, and
the first electrode also contacts the source/drain electrode in a second contact area that is exposed by a lower opening of the second via hole.

15. The display device as claimed in claim 11, wherein the second via hole overlaps a gate electrode of the transistor.

16. The display device as claimed in claim 1, wherein the transistor includes a gate electrode and two source/drain regions, and the gate electrode has a width that is narrower than a width of either of the source/drain regions.

17. A method of fabricating a display device, comprising;
forming a transistor on a substrate;
forming an intermediate layer on the transistor;
forming a source/drain electrode in a contact hole through the intermediate layer, the source/drain electrode being connected to the transistor and having an extension portion extending across an upper surface of the intermediate layer;
forming a via hole that exposes the extension portion; and
forming a light emitting structure on the intermediate layer, the light emitting structure being connected to the extension portion by a first electrode that is disposed in the via hole, wherein:
a contact area where the first electrode contacts the source/electrode has an area greater than an area of an opening of the contact hole at an upper surface of the intermediate layer, and
the contact area does not overlap the opening.

18. The method as claimed in claim 17, wherein the first electrode includes a first electrode layer and a second electrode layer, and forming the first electrode includes:
forming the first electrode layer on the substrate and in the via hole, the first electrode layer being on the contact area;
removing the first electrode layer from the contact area; and
forming the second electrode layer on the first electrode layer and on the contact area such that the second electrode layer directly contacts the source/drain electrode in the contact area.

19. The method as claimed in claim 18, wherein the first electrode layer is a reflective layer and the second electrode layer is a transparent conductive layer.

20. The method as claimed in claim 18, wherein removing the first electrode layer from the contact area includes:
forming a photoresist layer on the first electrode layer, the photoresist layer filling the via hole;
removing the photoresist layer from the via hole to expose the first electrode layer; and
removing the first electrode layer from the via hole where it is exposed by the photoresist layer.

21. The method as claimed in claim 20, wherein the photoresist layer is a positive photoresist.

22. The method as claimed in claim 17, wherein the via hole overlaps a gate electrode of the transistor in the layout.

23. The method as claimed in claim 17, further comprising:
forming a passivation layer on the intermediate layer and on the source/drain electrode; and
forming a planarization layer on the passivation layer.
